(19) United States
(12) Patent Application Publication
(10) Pub. No.: US 2024/0413245 A1
(43) Pub. Date: Dec. 12, 2024

(54) SEMICONDUCTOR DEVICES HAVING A SEAL RING

(71) Applicant: Samsung Electronics Co., Ltd., Suwon-si (KR)

(72) Inventors: In Namgung, Suwon-si (KR); Hwasung Rhee, Suwon-si (KR); Youngshil Kim, Suwon-si (KR); Hyokyeom Kim, Suwon-si (KR); Joonil Cha, Suwon-si (KR)

(21) Appl. No.: 18/666,932

(22) Filed: May 17, 2024

(30) Foreign Application Priority Data
Jun. 8, 2023 (KR) 10-2023-0073250

(51) Int. Cl. H01L 29/78; H01L 23/00

(52) U.S. Cl. CPC H01L 29/785; H01L 23/562; H01L 23/564

(57) ABSTRACT

A semiconductor device includes a substrate having a first region and a second region surrounding the first region, an integrated circuit structure disposed on the first region, and a seal ring structure disposed on the second region, wherein the integrated circuit structure includes a first active fin extending on the first region in a <110> crystal direction of the substrate, a first epitaxial pattern disposed on one region of the first active fin, and a first contact structure connected to the first epitaxial pattern, and the seal ring structure includes a second active fin extending on the second region in a <100> crystal direction of the substrate, a second epitaxial pattern disposed on the second active fin and including the same material as that of the first epitaxial pattern, and a second contact structure connected to the second epitaxial pattern.

### CROSS-REFERENCE TO RELATED APPLICATION(S)

This application claims benefit of priority under 35 U.S.C. § 119 to Korean Patent Application No. 10-2023-0073250, filed on Jun. 8, 2023, in the Korean Intellectual Property Office, the disclosure of which is incorporated herein by reference in its entirety.

### BACKGROUND

The present disclosure relates to semiconductor devices having a seal ring.

With an increase in the demand for high performance, high speed, and/or multi-functionalization of a semiconductor device, a degree of integration of semiconductor devices is increasing. A size of a transistor needs to be decreased to improve the integration of the semiconductor device. However, a decrease in the size of the transistor may cause a single-channel effect. In order to alleviate the single-channel effect, a fin field effect transistor (FinFET) in which a gate electrode is in contact with three sides of a channel structure has been developed. On the other hand, a peripheral region of the semiconductor device requires a seal ring to protect an internal chip region from moisture or cracks.

### SUMMARY

An aspect of the present disclosure is to provide a semiconductor device having a seal ring with improved reliability.

According to an aspect of the present disclosure, a semiconductor device includes: a substrate having a first region and a second region, the second region surrounding the first region; an integrated circuit structure disposed on the first region of the substrate; and a seal ring structure disposed on the second region of the substrate and surrounding the first region, wherein the integrated circuit structure includes: a first active fin extending on the first region of the substrate in a <110> crystal direction of the substrate, a gate structure intersecting the first active fin on the first region of the substrate, a first epitaxial pattern disposed on one region of the first active fin on at least one side of the gate structure and provided to a source/drain region, and a first contact structure connected to the first epitaxial pattern, and wherein the seal ring structure includes: a second active fin extending on the second region on the substrate in a <100> crystal direction of the substrate, a second epitaxial pattern disposed on the second active fin and including the same material as that of the first epitaxial pattern, and a second contact structure connected to the second epitaxial pattern.

According to an aspect of the present disclosure, a semiconductor device includes: a substrate having a first region and a second region, the second region surrounding the first region; a first active fin extending on the first region of the substrate in a <110> crystal direction; a gate structure intersecting one region of the first active fin on the second region of the substrate; a first epitaxial pattern disposed on the first active fin on both sides of the gate structure and provided to a source/drain region; a second active fin extending on the second region of the substrate in a <100> crystal direction and surrounding the first region; and a second epitaxial pattern disposed on the second active fin and including the same material as that of the source/drain region, wherein the first epitaxial pattern has a first cross-section in direction perpendicular to an extension direction of the first active fin, the second epitaxial pattern has a second cross-section in a direction perpendicular to an extension direction of the second active fin, and the first cross-section has a shape different from that of the second cross-section and has an area greater than that of the second cross-section.

According to an aspect of the present disclosure, a semiconductor device includes: a substrate having a device region and a sealing region surrounding the device region; an integrated circuit structure disposed on the device region of the substrate; a first seal ring structure disposed on an internal region of the sealing region of the substrate and surrounding the device region; and a second seal ring structure disposed on an external region of the sealing region of the substrate and surrounding the first seal ring structure, wherein the integrated circuit structure includes a first active fin extending on the device region in a <110> crystal direction of the substrate, a gate structure intersecting the first active fin on the device region of the substrate, a first epitaxial pattern disposed on one region of the first active fin on at least one side of the gate structure and provided to a source/drain region, and a first contact structure connected to the first epitaxial pattern, wherein the first seal ring structure includes a second active fin extending on the internal region of the sealing region in a <100> direction of the substrate, a second epitaxial pattern extending in an extending direction of the second active fin on the second active fin and including the same material as that of the first epitaxial pattern, and a second contact structure connected to one region of the second epitaxial pattern, and wherein the second seal ring structure includes a third active fin extending on the external region of the sealing region in a <100> direction or a <110> direction of the substrate, and a third contact structure connected to the third active fin.

According to an example embodiment of the present disclosure, an active fin of a seal ring structure extends in a direction different from an extension direction of the active fin of an integrated circuit structure to provide a favorable crystal plane for epitaxial growth, thereby effectively consuming residual source gas for an epitaxial layer at an edge of a device region. As a result, defects (e.g., a bridge phenomenon of pull-up elements in an SRAM) due to epitaxial overgrowth at the edge of the device region may be prevented.

Advantages and effects of the present application are not limited to the foregoing content and may be more easily understood in the process of describing a specific example embodiment of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic plan view illustrating a semiconductor device according to an example embodiment of the present disclosure;

FIG. 2 is a partially enlarged view illustrating a partial sealing region A of the semiconductor device of FIG. 1 according to an example embodiment of the present disclosure;

FIG. 3 is a view illustrating the partial region A of FIG. 2 and an arrangement of a wiring structure on the sealing region according to an example embodiment of the present disclosure;

FIGS. 4A to 4C are cross-sectional views along line I1-I1′, line I2-I2′, and line I3-I3′ of FIG. 3, respectively, according to an example embodiment of the present disclosure;

FIG. 5 is a partially enlarged view illustrating an edge region B1 of a device region of FIG. 1 according to an example embodiment of the present disclosure;

FIG. 6 is a cross-sectional view taken along line II-II′ of FIG. 5, and FIG. 7A and FIG. 7B are cross-sectional views taken along line III1-III1′ and line III2-III2′ of FIG. 5 according to an example embodiment of the present disclosure;

FIGS. 8, 9A, and 9B are cross-sectional views illustrating an epitaxial growth process for a source/drain in a sealing region A and integrated circuit regions B1 and B2 of the semiconductor device of FIG. 1, respectively, according to an example embodiment of the present disclosure;

FIG. 10 is a graph illustrating an effective thickness of silicon germanium according to a crystal plane of silicon according to an example embodiment of the present disclosure;

FIG. 11 is a cross-sectional view illustrating a semiconductor device according to an example embodiment of the present disclosure;

FIG. 12 is a schematic plan view illustrating a semiconductor device according to an example embodiment of the present disclosure;

FIG. 13 is a partially enlarged view illustrating a corner region A2 of the semiconductor device of FIG. 12 according to an example embodiment of the present disclosure;

FIG. 14 is a plan view illustrating an example second partial region A3 of the semiconductor device of FIG. 12 according to an example embodiment of the present disclosure;

FIG. 15 is a plan view illustrating an example second partial region A3 of the semiconductor device of FIG. 12 according to an example embodiment of the present disclosure;

FIG. 16 is a partially enlarged view illustrating a corner region C of the semiconductor device of FIG. 12 according to an example embodiment of the present disclosure; and

FIGS. 17A and 17B are plan views illustrating various examples of first and second sealing regions aligned in a partial region D of FIG. 16 according to an example embodiment of the present disclosure.

### DETAILED DESCRIPTION

Hereinafter, example embodiments of the present disclosure will be described with reference to the accompanying drawings. Like reference characters refer to like elements throughout.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

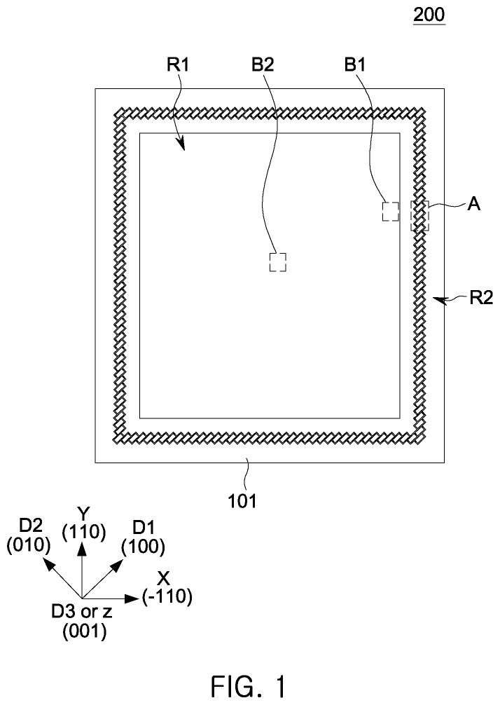

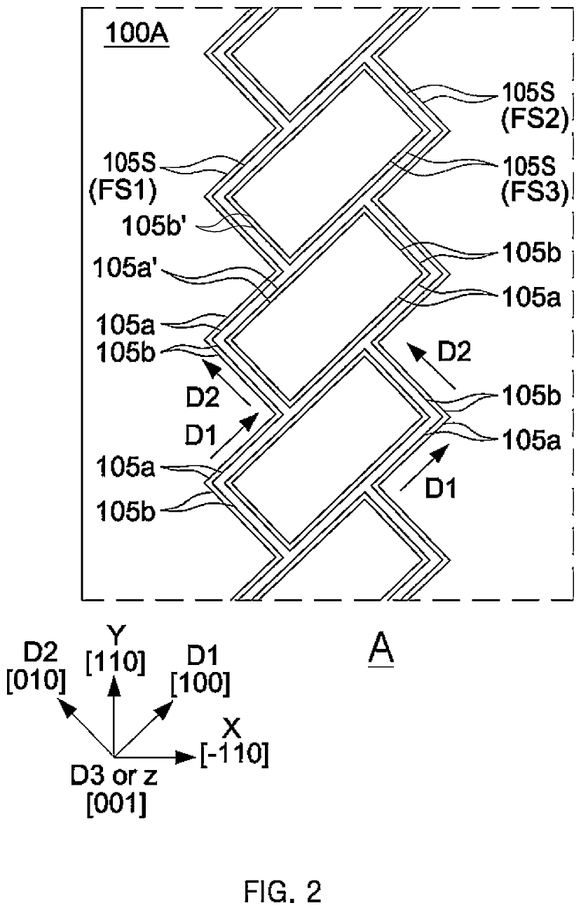

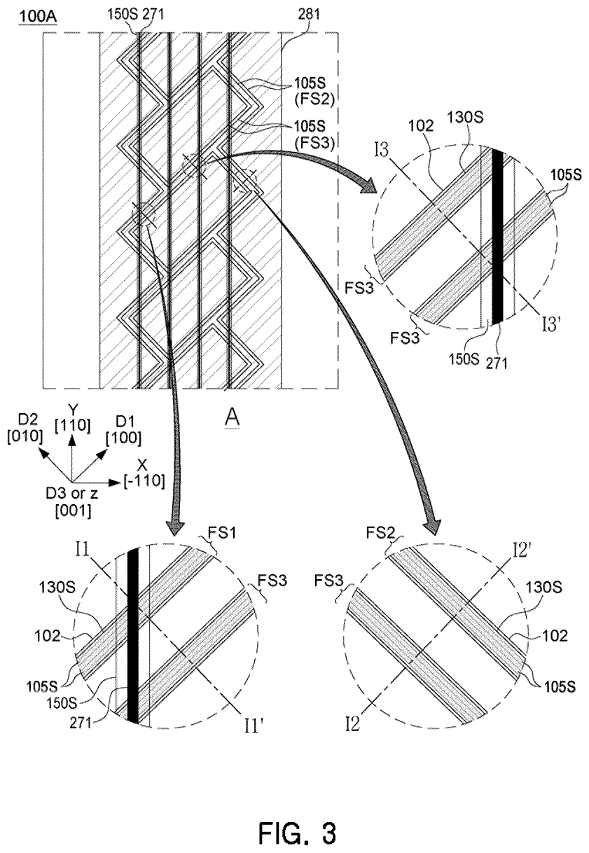

FIG. 1 is a schematic plan view illustrating a semiconductor device according to an example embodiment of the present disclosure, FIG. 2 is a partially enlarged view illustrating a partial region A of the semiconductor device of FIG. 1 according to an example embodiment of the present disclosure, and FIG. 3 is a view illustrating the partial region A of FIG. 2 and an arrangement of a wiring structure on the partial region A according to an example embodiment of the present disclosure.

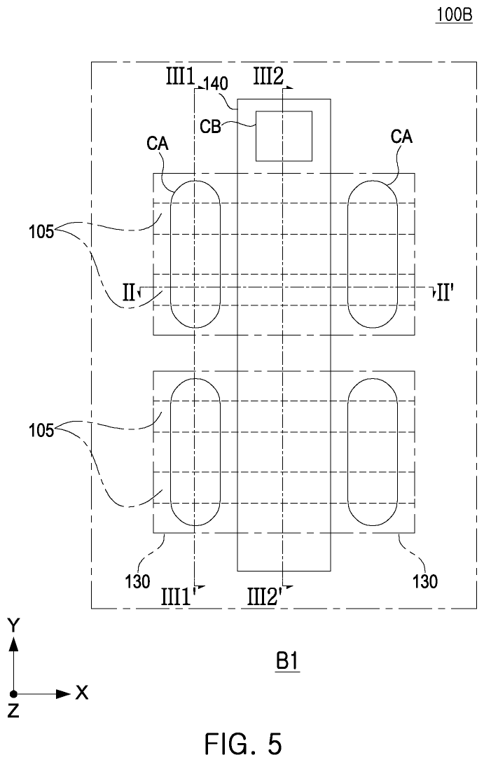

Referring to FIGS. 1 to 3, a semiconductor device 200 may include a substrate 101 having a first region R1 and a second region R2 surrounding the first region R1, an integrated circuit structure 100B (see FIGS. 5, 6, and 7A-7B) on the first region R1 of the substrate 101, and a seal ring structure 100A on the second region R2 of the substrate 101.

The first region R1 is a device region (or also referred to as an integrated circuit region) in which the integrated circuit structure 100B is formed, and may be a central region of the substrate 101. The second region R2 is a sealing region for blocking cracks and preventing moisture penetration to protect the device region, and may be an edge region of the substrate 101. The second region R2 may include a seal ring structure surrounding the first region R1. For example, the second region R2 may extend around the perimeter of the first region R1 and may completely surround the first region R1.

The substrate 101 may be formed of or include, for example, a semiconductor material such as Si or Ge, or a compound semiconductor material such as SiGe, SiC, GaAs, InAs, or InP. In another example, the substrate 101 may have a silicon on insulator (SOI) structure. An active region 102 may be provided on the substrate 101, and the active region 102 may be a conductive region such as a well doped with impurities or a structure doped with impurities. In an example embodiment of the present disclosure, the active region 102 may be an N-type well for a P-type transistor or a P-type well for an N-type transistor, respectively, but the present disclosure is not limited thereto. The integrated circuit structure 100B disposed in the first region R1 of the substrate 101 may include a semiconductor element having first and second active fins 105 and 105S of a three-dimensional structure, such as a P-type transistor and/or an N-type transistor.

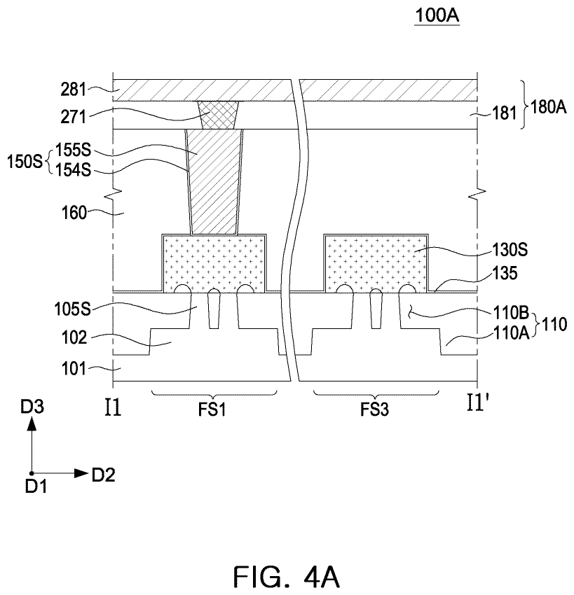

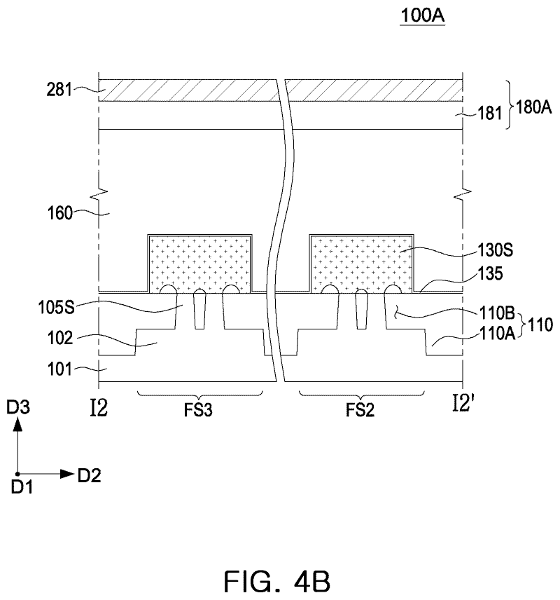

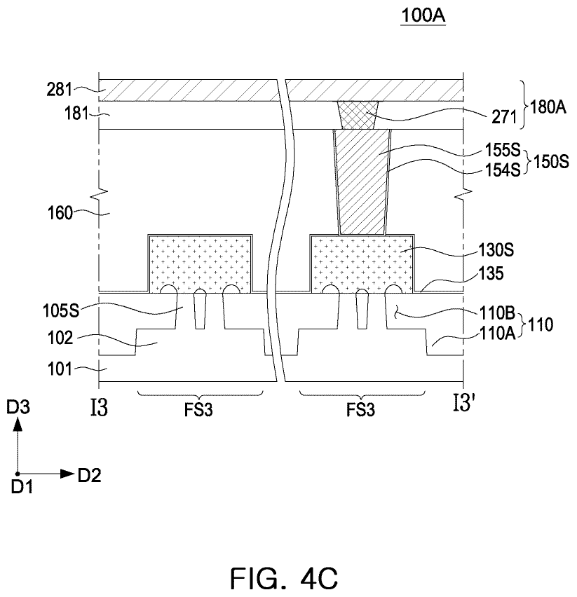

FIGS. 4A to 4C are cross-sectional views taken by cutting the sealing region of FIG. 3 into line I1-I1′, line I2-I2′, and line I3-I3′, respectively.

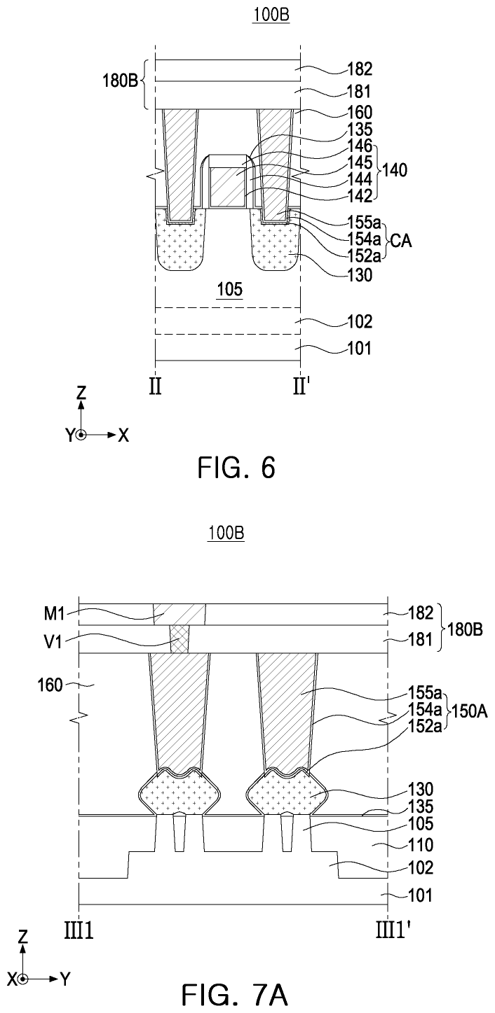

Referring to FIGS. 6 and 7A and 7B together with FIGS. 4A to 4C, a device isolation layer 110 may be disposed on the substrate 101 to surround first and second active fins 105 and 105S. Some of the first and second active fins 105 and 105S may protrude from an upper surface of the device isolation layer 110. For example, the device isolation layer 110 may be formed of or include a silicon oxide or a silicon oxide-based insulating material. The device isolation layer 110 may be divided into a first device isolation layer 110A defining the active regions 102 and a second device isolation layer 110B defining the first and second active fins 105 and 105S (see FIG. 4A). The first device isolation layer 110A may have a bottom surface deeper than that of the second device isolation layer 110B. For example, the first device isolation layer 110A may be referred to as deep trench isolation (DTI), and the second device isolation layer 110B may be referred to as shallow trench isolation (STI).

In an example embodiment of the present disclosure, the integrated circuit structure 100B on the first region R1 of the substrate 101 includes the first active fins 105 extending in a <110> crystal direction of the substrate 101 (see FIG. 5), while the seal ring structure 100A on the second region R2 of the substrate 101 includes the second active fins 105S extending in a <100> direction of the substrate 101 (e.g., a direction D1 or a direction D2), different from an extension direction (e.g., an X-direction) of the first active fin 105 (see FIGS. 2 and 3).

A change in an extension direction of the second active fin 105S of the seal ring structure 100A may solve a local epitaxial overgrowth problem in a source/drain formation process during a manufacturing process of a semiconductor device 200. Specifically, source gases remaining during formation of a source/drain are concentrated on an edge of a device region R1, and a first epitaxial pattern 130 is overgrown on the first active fin 105 disposed adjacently to the edge, which may result in a cause of defects. For example, in SRAM elements, epitaxial patterns of adjacent pull-up elements (e.g., a P-type MOSFET) may overgrow and bridge each other.

In an example embodiment of the present disclosure, since the second active fin 105S has a {100} crystal plane that is more advantageous for epitaxial (e.g., SiGe) growth than a {110} crystal plane of the first active fin 105, a second epitaxial pattern 130S may grow from the second active fin 105S by a relatively large volume (or an effective thickness), and accordingly, the second active fin 105S disposed in a sealing region R2 may effectively consume the source gas remaining in an edge region of an entire substrate 101. Accordingly, a disadvantageous epitaxial layer may be prevented from overgrowing in the edge of the device region R1.

The second active fins 105S may include fin components 105a, 105b, 105a′, and 105b′ extending in different directions belonging to the <100> direction, and may be arranged in various patterns. FIG. 2 illustrates an arrangement of the second active fins 105S of a seal ring structure 100A adopted in an example embodiment of the present disclosure.

Referring to FIG. 2, the seal ring structure 100A includes first to third fin structures FS1, FS2, and FS3, each having two second active fins 105S. Each of the first to third fin structures FS1, FS2, and FS3 may have unique patterns including fin components 105a, 105b, 105a′, and 105b′ extending lengthwise in different directions belonging to a <100> crystal direction. In an example embodiment of the present disclosure, the first to third fin structures FS1, FS2, and FS3 may configure an arrangement in which rectangular patterns inclined in a direction D1 (e.g., [100]) are repeated. As illustrated in FIG. 1, the inclined rectangular patterns may be arranged in a first direction (e.g., an X-direction) and a second direction (e.g., a Y-direction) to surround the device region R1.

Specifically, the first fin structure FS1 may have a zigzag pattern in which the first fin components 105a extending lengthwise in the direction D1 (e.g., [100]) and the second fin components 105b extending lengthwise in a direction D2 (e.g., [010]), perpendicular to the direction D1 are alternately arranged. The first fin structure FS1 may proceed in the Y-direction (e.g., [110]) of a left side of FIG. 2.

Similarly, the second fin structure FS2 may have a zigzag pattern in which the first fin components 105a extending lengthwise in the direction D1 (e.g., [100]) and the second fin components 105b extending lengthwise in the direction D2 (e.g., [010]) are alternately arranged. The second fin structure FS2 may proceed in the Y-direction (e.g.,) [110])from a right side of FIG. 2 to face the first fin structure FS1, and the first and second fin structures FS1 and FS2 may be disposed to form rectangular spaces inclined in the direction D1 (e.g., [100]) therebetween.

In rectangular spaces between the first and second fin structures FS1 and FS2, a plurality of third fin structures FS3 having a rectangular pattern respectively corresponding to the spaces may be disposed. Each of the plurality of third fin structures FS3 may include two first fin components 105a and 105a′ extending in the direction D1 (e.g., [100]) and arranged in parallel with each other, and two second fin components 105b and 105b′ extending in the direction D2 (e.g., [010]) and arranged in parallel with each other.

As described above, in the example embodiment of the present disclosure, since each of the first to third fin structures FS1, FS2, and FS3 includes two active fins, it may be disposed on eight active fins in an external direction (e.g., the X-direction in FIG. 2) of the semiconductor device 200 from the device region R1 to perform a sealing function. For example, in the embodiment of FIGS. 1 to 3, an imaginary line extending in the X-direction may cross eight active fins in the sealing region R2.

Furthermore, the second active fins 105S may be formed to have the same width, height, and interval as those of the first active fins 105 (e.g., see FIGS. 5 to 7B) of the seal ring structure 100A, and in some example embodiments, the second active fins 105S and the first active fins 105 may be formed to have different widths, heights, and/or intervals. For example, the second active fins 105S may have a width greater than that of the first active fins 105.

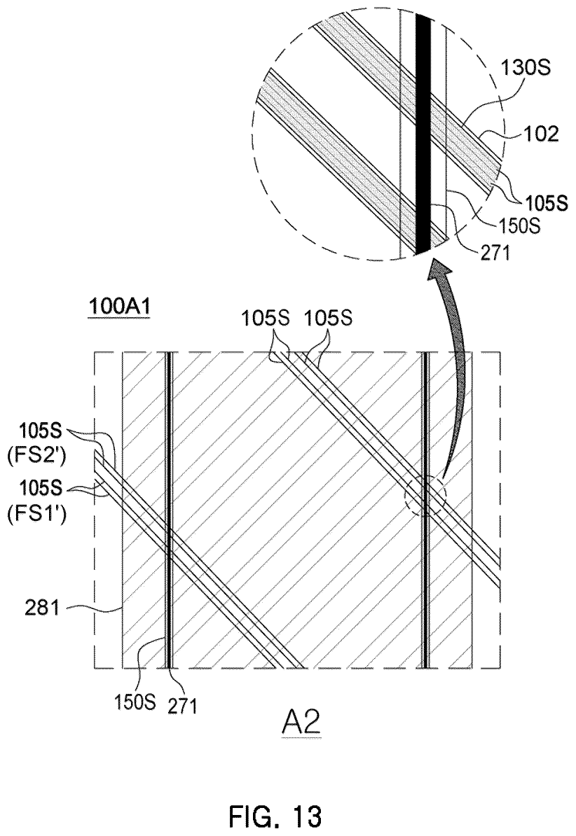

In an example embodiment of the present disclosure, the fin structures adopted in the seal ring structure 100A may have various arrangements other than the arrangement of FIG. 2. For example, in addition to exemplified patterns of the first to third fin structures FS1, FS2, and FS3, a fin structure may have different patterns comprised of fin components in different directions of the <100> direction (e.g., see FIGS. 13, 14 and 15). Furthermore, in some example embodiments, each of the fin structures may include a different number of active fins (e.g., four active fins). For example, the number of active fins in each fin structure may be determined by an active fin formation process (e.g., double patterning).

As described above, since the second active fin 105S adopted in the example embodiment of the present disclosure has a {100} crystal plane that is more advantageous for epitaxial (e.g., SiGe) growth than the {110} crystal plane of the first active fin 105, a source gas remaining on the edge of the device region R1 may be effectively consumed, and accordingly, disadvantageous epitaxial patterns and defects resulting therefrom may be prevented from overgrowing on the edge of the device region R1.

Referring to FIGS. 6 and 7A and 7B together with FIGS. 3 and 4A to 4C, the semiconductor device 200 according to an example embodiment of the present disclosure may include first and second epitaxial patterns 130 and 130S formed on the first and second active fins 105 and 105S, respectively, and an interlayer insulating layer 160 covering the first and second epitaxial patterns 130 and 130S. The interlayer insulating layer 160 may be formed of or include, for example, flowable oxide (FOX), Tonen SilaZen (TOSZ), undoped silica glass (USG), Borosilica glass (BSG), PhosphoSilaca glass (PSG), BoroPhosphoSilica glass (BPSG), plasma enhanced Tetra Ethyl Ortho Silicate (PETEOS), Fluoride Silicate glass (FSG), high density plasma (HDP) oxide, plasma enhanced oxide (PEOX), flowable CVD (FCVD) oxide, or combinations thereof. The interlayer insulating layer 160 may be formed using chemical vapor deposition (CVD), a flowable-CVD process, or a spin coating process.

In the semiconductor device 200 according to an example embodiment of the present disclosure, a circuit wiring structure 180B and a sealing wiring structure 180A may be disposed on the interlayer insulating layer 160 corresponding to the device region R1 and the sealing region R2, respectively. The sealing wiring structure 180A and the circuit wiring structure 180B are described separately from each other, but may actually be formed at the same time through the same process.

FIG. 3 is a view illustrating the sealing region R2 of FIG. 2 and an arrangement of a sealing wiring structure 180A on the sealing region R2, and FIGS. 4A to 4C are cross-sectional views taken by cutting the sealing region R2 of FIG. 3 into line I1-I1′, line I2-I2′, and line I3-I3′, respectively. Here, it may be understood that FIG. 3 illustrates an arrangement of a second contact structure 150S and a sealing wiring structure 180A provided on an arrangement of the second active fins 105S of FIG. 2. First, according to FIGS. 3 and 4A to 4C, a seal ring structure 100A may further

include a second epitaxial pattern 130S disposed on a second active fin 105S and extending on the sealing region R2 of the substrate 101 in a <100> direction of a substrate 101, and a second contact structure 150S connected to the second epitaxial pattern 130S. In example embodiments, a lower surface of the second contact structure 150S may contact an upper surface of the second epitaxial pattern 130S.

In an example embodiment of the present disclosure, the second epitaxial pattern 130S may extend from an upper surface of the second active fin 105S in the <100> direction. In this manner, since the second epitaxial pattern 130S is formed over a sufficient area on the second active fin 105S, residual source gas concentrated on the device region R1 may be effectively consumed. In some example embodiments, the second epitaxial pattern 130S may be formed substantially over an entire upper surface of the second active fins 105S. For example, the second epitaxial pattern 130S may contact the upper surface of the second active fins 105S.

The second epitaxial pattern 130S may be formed of or include the same material as that of a first epitaxial pattern 130 (see FIG. 7A) (especially, a source/drain of a P-type transistor) on a first active fin 105. For example, the second epitaxial pattern 130S may be formed of or include SiGe.

As described above, since the second active fin 105S extends in the <100> direction unlike an extension direction of the first active fin, it has a {100} crystal plane that is more advantageous for epitaxial (e.g., SiGe) growth than a {110} crystal plane of the first active fin 105. Accordingly, the second epitaxial pattern 130S having a relatively large volume may grow in the second active fin 105S.

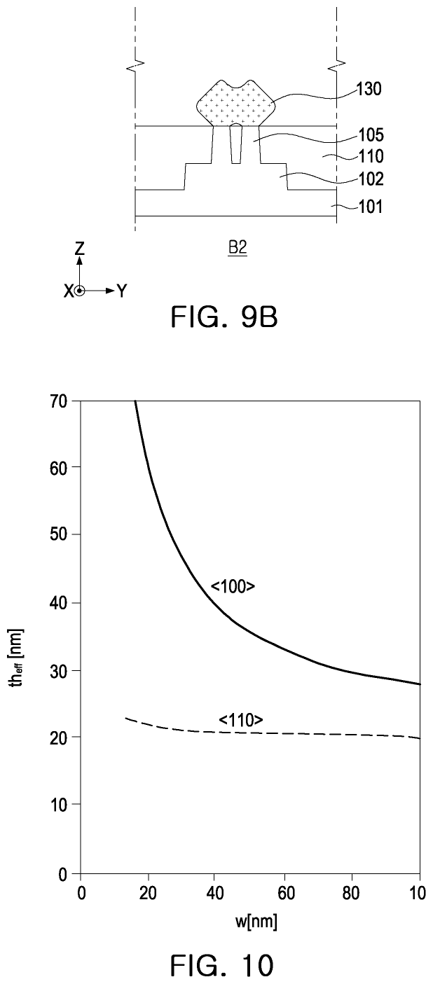

As illustrated in FIGS. 4A to 4C, the second epitaxial pattern 130S has a substantially rectangular shape when viewed in a cross-section in a direction D1, perpendicular to an extension direction (e.g., direction D2) of a second active fin 105. The second epitaxial pattern 130S may have an upper surface substantially parallel to an upper surface of the substrate 101. On the other hand, since the first and second epitaxial patterns 130 and 130S grow from different crystal surfaces, the cross-section of the second epitaxial pattern 130S has a different shape (e.g., a square shape) from a cross-section of the first epitaxial pattern 130 (see FIG. 7A; a cross-section perpendicular to the extension direction of the first active fin 105) under the same conditions. Furthermore, the cross-section of the second epitaxial pattern 130S may have a larger area than the cross-section of the first epitaxial pattern 130 (see FIG. 7A; a cross-section perpendicular to the extension direction of the first active fin 105) under the same conditions. A change in the extension direction of the second active fins 105S may effectively consume source gas remaining in an edge region of an entire substrate 101 to prevent overgrowth of an epitaxial pattern in a local region. Such an effect will be described in detail with reference to FIGS. 9, 10A and 10B.

In an example embodiment of the present disclosure, the second contact structure 150S may be connected to the second epitaxial pattern 130S by penetrating through the interlayer insulating layer 160 (see FIGS. 4A and 4C). Furthermore, the second contact structure 150S may have a line pattern extending in a first direction (e.g., an X-direction) and/or a second direction (e.g., a Y-direction) so as to intersect the second active fin 105S, that is, the second epitaxial pattern 130S. For example, the second contact structure 150S may extend lengthwise in the first direction (e.g., an X-direction) and/or the second direction (e.g., a Y-direction). Referring to FIG. 3, the second contact structure 150S may extend lengthwise in the second direction (e.g., the Y-direction) so as to intersect the second active fin 105S and the second epitaxial pattern 130S.

Accordingly, referring to enlarged regions of FIG. 3 and cross-sections thereof (FIGS. 4A to 4C), four second contact structures 150S may be connected only to a partial region of the second active fin 105S or the second epitaxial pattern 130S, that is, a partial region intersecting the second contact structure 150S.

Specifically, in FIG. 3, the second contact structure 150S on the left intersects a first fin structure FS1 and a third fin structure FS3 in different regions, but in any cross-section perpendicular to the extension direction of the second active fin 105S, the second contact structure 150S may be connected to either of the first and third fin structures FS1 and FS3, or may not be connected to both of them. For example, in a cross-section of FIG. 4A, the second contact structure 150S may be connected only to the second epitaxial pattern 130S of the first fin structure FS1, but may not be connected to the second epitaxial pattern 130S of the third fin structure FS3.

Similarly, in FIG. 3, the second contact structure 150S on the right intersects a second fin structure FS2 and the third fin structure FS3 in different regions, but in any cross-section perpendicular to the extension direction of the second active fin 105S, the second contact structure 150S may not be connected to either of the second and third fin structures FS1 and FS3, or may not be connected to both of them. For example, in a cross-section of FIG. 4B, the second contact structure 150S may not be connected to both the second epitaxial pattern 130S of the second and third fin structures FS2 and FS3.

In FIG. 3, two central second contact structures 150S may intersect a plurality of third fin structures FS3 in different regions, but in any cross-section perpendicular to the extension direction of the second active fin 105S, the second contact structure 150S may be connected to any one of two adjacent third fin structures FS3, or may not be connected to both of them. For example, in a cross-section of FIG. 4C, the second contact structure 150S may be connected only to the second epitaxial pattern 130S of one of the two adjacent third fin structures FS3.

The second contact structure 150S may include a second barrier layer 154S and a second contact plug 155S. The second barrier layer 154S may surround a side surface of the second contact plug 155S and cover a lower surface of the second contact plug 155S. For example, the second barrier layer 154S may contact the side and lower surfaces of the second contact plug 155S. The second barrier layer 154S may be formed of or include a metal nitride such as a titanium nitride film (TiN), a tantalum nitride film (TaN), or a tungsten nitride film (WN). The second contact plug 155S may be formed of or include, for example, tungsten (W), cobalt (Co), titanium (Ti), alloys thereof, or combinations thereof.

In some example embodiments of the present disclosure, the semiconductor device 200 may include first and second epitaxial patterns 130 and 130S and an etching stop layer 135 conformally formed on a device isolation layer 110 (see FIGS. 4A to 4C, 6 and 7A) and the first and second epitaxial patterns 130 and 130S. The etching stop layer 135 may contact an upper surface of the device isolation layer 110 and upper and side surfaces of the first and second epitaxial patterns 130 and 130S. The etching stop layer 135 may be used in a process of forming a contact hole for the first and second contact structures 150A and 150S. In the process of forming the source/drain during the semiconductor manufacturing process, some of the first and second active fins 105 and 105S may be removed and a selective epitaxial growth (SEG) process may be performed to form the first and second epitaxial patterns 130 and 130S on the first and second active fins 105 and 105S, respectively. Before forming the interlayer insulating layer 160, the etching stop layer 135 covering the device isolation layer 110S and the first and second epitaxial patterns 130 and 130S may be formed. The etching stop layer 135 may be formed of or include, for example, at least one of SIN, SiCN, SiOC, SiON, and SiOCN.

The seal ring structure 100A adopted in an example embodiment of the present disclosure may include a sealing wiring structure 180A on the interlayer insulating layer 160 as described above.

Referring to FIGS. 3 and 4A TO 4C, the sealing wiring structure 180A may include first and second wiring insulating layers 181 and 182 sequentially disposed on the interlayer insulating layer 160, a second metal via 271 connected to a second contact structure 150S by penetrating through the first wiring insulating layer 181, and a second metal line 281 disposed in the second wiring insulating layer 182 and connected to the second metal via 271. For example, the first wiring insulating layer 181 may contact an upper surface of the interlayer insulating layer 160, and the second wiring insulating layer 182 may contact an upper surface of the first wiring insulating layer 181. The first wiring insulating layer 181 may contact side surfaces of the second metal via 271, and the second wiring insulating layer 182 may contact side surfaces of the second metal line 281. In some example embodiments of the present disclosure, a sealing wiring structure 180A and a circuit wiring structure 180B are exemplified as a single metal line, but may further include an additional metal line or a metal via to include a multilayer metal line.

Referring to FIG. 3, in an example embodiment of the present disclosure, a second metal via 271 may include a plurality of line-type second metal vias 271 extending along a plurality of second contact structures 150S in the second direction (e.g., the Y-direction). In such an embodiment, each second metal via 271 may contact a corresponding one of the second contact structures 150S. Furthermore, a second metal line 281 adopted in an example embodiment of the present disclosure extends in the second direction (e.g., the Y-direction) and may have a width extending in the first direction (e.g., the X-direction). For example, the second metal line 281 may have a width to cover a region in which the second active fins 105S are arranged, as illustrated in FIG. 3.

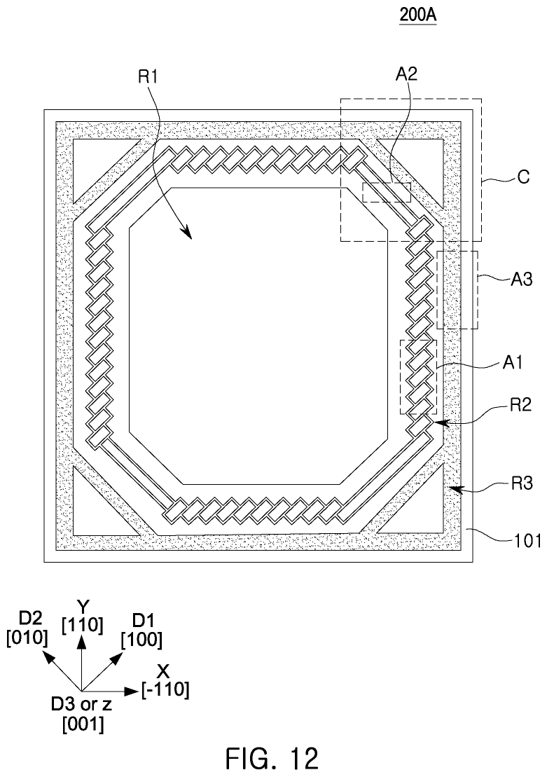

FIG. 3 illustrates only partial region A adjacent to one side of a semiconductor device, and a seal ring structure 100A has a shape surrounding the device region R1 in the sealing region R2, as illustrated in FIG. 1. The seal ring structure 100A adopted in an example embodiment of the present disclosure may have a rectangular shape in a plan view. Accordingly, in upper and lower portions of the seal ring structure 100A illustrated in FIG. 1 (e.g., the portions of the seal ring structure 100A extending in the first direction (the X-direction)), the second contact structure 150S, the second metal via 271, and the second metal line 281 may extend in the first direction (e.g., the X-direction) and have a rectangular shape from a plan view. In some example embodiments of the present disclosure, a seal ring structure 100A may have a different shape from a plan view (see FIG. 12). Furthermore, a plurality of such seal ring structures may be disposed in the sealing region (see FIG. 12).

In some example embodiments of the present disclosure, a sealing wiring structure 180A and the circuit wiring structure 180B may not be electrically connected to each other between metal lines. The second metal line 281 and the second metal via 271 of the sealing wiring structure 180A may ground the second contact structure 150S and the second active fins 105S to the substrate 101. Accordingly, static current that may flow into the integrated circuit structure 100B from the outside may be minimized and electrical damage to the integrated circuit structure 100B may be prevented.

As described above, the seal ring structure 100A adopted in an example embodiment of the present disclosure may be provided in the sealing region R2 of a plurality of semiconductor devices 200 of a wafer, and may prevent moisture from penetrating into the device region RI or prevent occurrence of cracks during a dicing process of separating the semiconductor devices 200, thereby protecting an integrated circuit.

Hereinafter, a structure of an integrated circuit structure 100B disposed in a device region R1 will be described in detail.

FIG. 5 is a partially enlarged view illustrating an edge region B1 of the device region R1 of FIG. 1 according to an example embodiment of the present disclosure, FIG. 6 is a cross-sectional view taken by cutting the edge region B1 of FIG. 5 into line II-II′, and FIG. 7A and FIG. 7B are cross-sectional views taken by cutting the edge region B1 of FIG. 5 into line III1-III1′ and line III2-III2′.

Referring to FIGS. 5 to 7B, a semiconductor device 200 according to an example embodiment of the present disclosure includes an integrated circuit structure 100B disposed in a first region R of a substrate 101. The integrated circuit structure 100B employed in an example embodiment of the present disclosure may include first active fins 105 extending lengthwise in a <111> crystal direction that is a first direction (e.g., the X-direction) on the substrate 101, a device isolation layer 110 defining the first active fins 105, and a gate structure 140 extending in a second direction (e.g., the Y-direction) intersecting the first active fins 105, and first epitaxial patterns 130 provided as a source/drain region on the first active fins 105 disposed adjacently to a side surface of the gate structure 140. In the description of the integrated circuit structure 100B, a description of the configuration identical to or similar to the configuration of the seal ring structure is omitted, and a description of a corresponding configuration of the seal ring structure may be referenced.

In an example embodiment of the present disclosure, the integrated circuit structure 100B may be a FinFET as a transistor in which a channel region is formed in a region of the first active fins 105 intersecting the gate structure 140.

Unlike a second active fin 105S extending in a <100> direction (e.g., D1 or D2) of a substrate, the first active fins 105 adopted in an example embodiment of the present disclosure extend in a <110> crystal direction (e.g., the X-direction) of the substrate, as described above. In some example embodiments of the present disclosure, the first active fins 105 may include impurities, for example, the first active fins 105 may include N-type impurities.

The gate structure 140 may extend in a second direction (e.g., the Y-direction) by intersecting the first active fins 105 from an upper portion of the first active fins 105. The gate structure 140 may include a gate electrode 145, a gate dielectric layer 142 disposed between the gate electrode 145 and the first active fins 105, gate spacers 144 on side surfaces of the gate electrode 145, and a gate capping layer 146 on the gate electrode 145.

The gate dielectric layer 142 may be disposed between the first active fins 105 and the gate electrode 145. The gate dielectric layer 142 may be disposed to surround all surfaces except for an uppermost surface of the gate electrode 145. For example, the gate dielectric layer 142 may contact the lower and side surfaces of the gate electrode 145. The gate dielectric layer 142 may be formed of or include an oxide, a nitride, or a high-K material. The gate electrode 145 may extend from an upper portion of the first active fins 105 to intersect the first active fins 105. The gate electrode 145 may be formed of or include a conductive material, for example, a metal nitride such as a titanium nitride film (TiN), a tantalum nitride film (TaN), or a tungsten nitride film (WN), and/or a metallic material such as aluminum (Al), tungsten (W) or molybdenum (Mo), or a semiconductor material such as doped polysilicon. In some example embodiments of the present disclosure, the gate electrode 145 may be comprised of two or more multilayers.

The gate spacer 144 may be disposed on both sides of the gate electrode 145 and may extend in a direction (e.g., in a Z-direction), perpendicular to an upper surface of a substrate 101. In some example embodiments of the present disclosure, the gate spacer 144 may include a multilayer structure. The gate spacer 144 may be formed of or include an oxide, a nitride, and an oxynitride. The gate capping layer 146 may be disposed on the gate electrode 145. The gate capping layer 146 may extend in the second direction (e.g., Y-direction) along an upper surface of the gate electrode 145. For example, the gate capping layer 146 may be formed of or include an oxide, a nitride, and an oxynitride.

A region of the first active fins 105 on both sides of the gate structure 140 may be partially recessed, and first epitaxial patterns 130 for a source/drain may be selectively re-grown in each of the recessed regions. The first epitaxial patterns 130 are also referred to as a raised source/drain (RSD). For example, the first epitaxial patterns 130 may be formed of or include Si, SiGe, or Ge, and may have a conductive type of either an N type or a P type. When forming a P-type source/drain region, the first epitaxial patterns 130 may be re-grown into SiGe, and may be doped with P-type impurities such as boron (B), indium (In), gallium (Ga), and boron trifluoride (BF3). When forming silicon (Si) in an N-type source/drain region, the first epitaxial patterns 130 may be doped with N-type impurities such as phosphorus (P), nitrogen (N), arsenic (As), and antimony (Sb). The first epitaxial patterns 130 may have different shapes along a crystallographically stable surface during a growth process. For example, referring to FIG. 7A, the first epitaxial patterns 130 may have a pentagonal cross-section, and such a transistor may be a P-type transistor. Alternatively, the integrated circuit structure 100B may include an N-type transistor. The first epitaxial pattern of the N-type transistor may have a cross-section in a hexagonal shape or a polygonal shape having a gentle angle.

A semiconductor device 200 according to an example embodiment of the present disclosure includes a device isolation layer 110 on the substrate 101 and an interlayer insulating layer 160 on the device isolation layers 110, as described above. Referring to FIGS. 5, 6, 7A, and 7B, the integrated circuit structure 100B may include a first contact structure CA (also referred to as first contact structures 150A) connected to the first epitaxial patterns 130 by penetrating through the interlayer insulating layer 160 and a gate contact structure CB (also referred to as gate contact structures 150B) electrically connected to the gate electrode 145 by penetrating through the interlayer insulating layer 160.

The first contact structures 150A may be disposed on the first epitaxial pattern 130 and may have a length extending in the second direction (e.g., the Y-direction) as illustrated in FIG. 5. The first contact structures 150A may include a metal-semiconductor compound layer 152a, a first barrier layer 154a, and a first contact plug 155a. The first barrier layer 154a may surround the first contact plug 155a. The first barrier layer 154a may cover a lower surface of the first contact plug 155a. For example, the first barrier layer 154a may contact the lower and side surfaces of the first contact plug 155a. An upper surface of the first contact plug 155a may be substantially coplanar with an upper surface of the interlayer insulating layer 160.

The metal-semiconductor compound layer 152a may be disposed between the first barrier layer 154a and the first epitaxial patterns 130. For example, the metal-semiconductor compound layer 152a may be formed of or include metal silicide, metal germanide, or metal silicide-germanide. Here, the metal may be Ti, Ni, Ta, Co, or W, and the semiconductor may be Si, Ge, or SiGe.

Referring to FIGS. 5 and 7B, the gate contact structure CB (e.g., gate contact structure 150B) may be electrically connected to the gate electrode 145 by penetrating through the interlayer insulating layer 160 and the gate capping layer 146. The gate contact structure CB may include a gate barrier layer 154b and a gate contact plug 155b. The gate barrier layer 154b may surround the gate contact plug 155b. The gate barrier layer 154b may cover a lower surface of the gate contact plug 155b. For example, the gate barrier layer 154b may contact the lower and side surfaces of the gate contact plug 155b. An upper surface of the gate contact plug 155b may be substantially coplanar with an upper surface of the interlayer insulating layer 160 and/or an upper surface of the first contact plug 155a.

For example, the first barrier layer 154a and the gate barrier layer 154b may be formed of or include metal nitrides such as a titanium nitriding film (TiN), a tantalum nitriding film (TaN), or a tungsten nitriding film (WN). The first contact plug 155a and the gate contact plug 155b may be formed of or include, for example, tungsten (W), cobalt (Co), titanium (Ti), alloys thereof, or combinations thereof.

As described above, the semiconductor device 200 according to an example embodiment of the present disclosure may have a circuit wiring structure 180B and a sealing wiring structure 180A on the interlayer insulating layer 160 corresponding to the device region R1 and the sealing region R2, respectively.

As illustrated in FIGS. 6, 7A, and 7B, the integrated circuit structure 100B may further include a circuit wiring structure 180B on the interlayer insulating layer 160. The circuit wiring structure 180B may include first and second wiring insulating layers 181 and 182 sequentially disposed on the interlayer insulating layer 160, a first metal via V1 connected to the first contact structure 150A, and a first metal line M1 connected to the first metal via V1. For example, the first wiring insulating layer 181 may contact an upper surface of the interlayer insulating layer 160 and upper surfaces of the first contact structures 150A, and the second wiring insulating layer 182 may contact an upper surface of the first wiring insulating layer 181. The first wiring insulating layer 181 may contact side surfaces of the first metal via V1, and the second wiring insulating layer 182 may contact side surfaces of the first metal line M1. Over first and second regions R1 and R2, each of first and second wiring insulating layers 181 and 182 is a dielectric layer, the first metal via V1 may be disposed on a level corresponding to that of a second metal via 271 of the sealing wiring structure 180A, and the first metal line M1 may be disposed on a level corresponding to that of a second metal line 281 of the sealing wiring structure 180A. For example, upper surfaces of the first metal vias V and the second metal vias 271 may be coplanar with an upper surface of the first wiring insulating layer 181, lower surfaces of the first metal vias V and the second metal vias 271 may be coplanar with a lower surface of the first wiring insulating layer 181, upper surfaces of the first metal line Ml and the second metal line 281 may be coplanar with an upper surface of the second wiring insulating layer 182, and lower surfaces of the first metal line M1 and the second metal line 281 may be coplanar with a lower surface of the second wiring insulating layer 182.

As described above, the sealing wiring structure 180A and the circuit wiring structure 180B are described separately from each other, but actually, the sealing wiring structure 180A and the circuit wiring structure 180B may be formed at the same time through the same process. For example, the first and second metal vias 271 and V1 and the first and second metal lines 281 and M2 may be formed of or include copper or a copper-containing alloy.

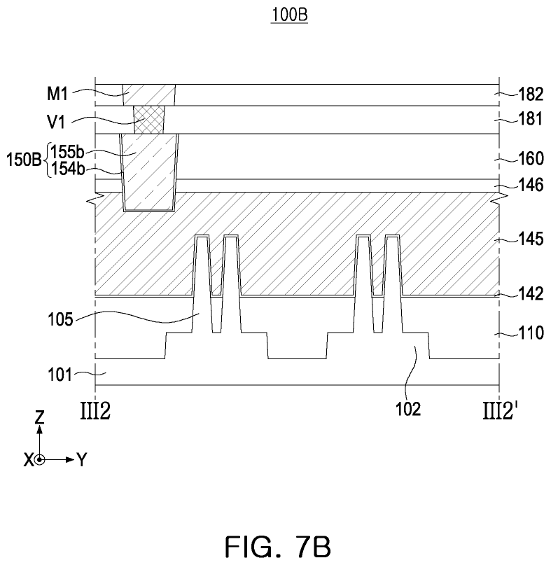

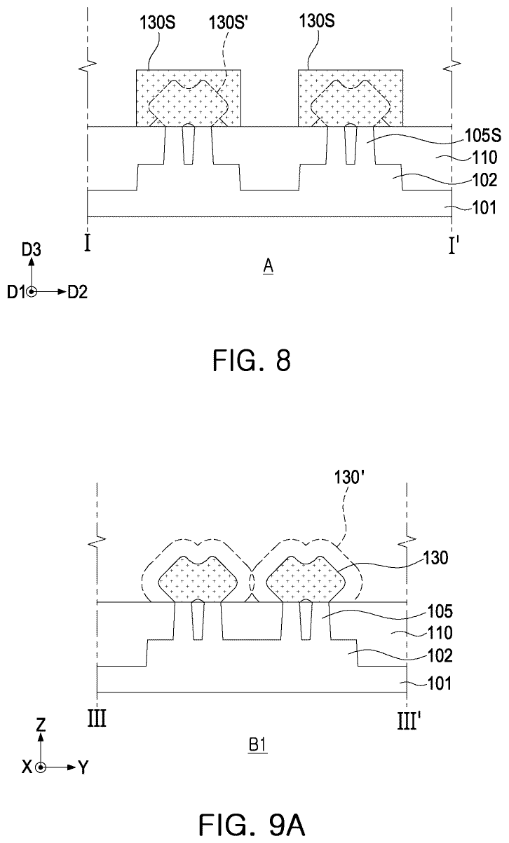

FIGS. 8, 9A, and 9B are cross-sectional views illustrating an epitaxial growth process for a source/drain in different regions B1 and B2 of an integrated circuit region and a sealing region A of a semiconductor device according to an example embodiment of the present disclosure, respectively.

FIG. 8 illustrates an integrated circuit structure disposed in a partial region A of the sealing region R2 of FIG. 1, FIG. 9A illustrates an integrated circuit structure disposed in an edge region B1 of the device region R1 of FIG. 1, and FIG. 9B illustrates an integrated circuit structure disposed in a central region B2 of the device region R1 of FIG. 1. A first epitaxial patterns 130 grown in FIGS. 9A and 9B include the same SiGe as a second epitaxial pattern 130S of FIG. 8, and may be understood to be performed through one epitaxial growth process for a P-type source/drain.

First of all, unlike the example embodiment of the present disclosure, when a second active fin 105S of FIG. 8 extends in the same direction as the first active fins 105, that is, in a <110> direction of a substrate 101, the source gas for epitaxial (e.g., SiGe) may be not consumed all in an integrated circuit region R1, and residual source gas may be concentrated on an edge region B1 during an epitaxial growth process. Due to the concentration of residual source gas, a first epitaxial pattern 130′ of the edge region B1 may be more overgrown than the first epitaxial pattern 130 of a central region B2 even in one integrated circuit region R1. As indicated by a dotted line in FIG. 9A, the first epitaxial pattern 130′ overgrown on a first active fin 105 may merge with other adjacent epitaxial patterns to cause defects. For example, in SRAM elements, the epitaxial patterns of adjacent pull-up devices (e.g., a P-type MOSFET) may overgrow and bridge each other. As illustrated in FIG. 8, since a second epitaxial pattern (130S′ indicated by a dotted line) grown from the second active fin 105S formed in the same direction (i.e., a <110> crystal direction) has the same crystal surface as the first active fin 105, it may have a cross-sectional shape identical to or similar to that of the first epitaxial pattern 130.

In contrast, in an example embodiment of the present disclosure, as illustrated in FIGS. 9A and 9B, the first active fins 105 are portions of the integrated circuit structure 100B and extend from a first region R1 of the substrate 101 in a <110> direction of the substrate 101, but, as illustrated in FIG. 8, the second active fins 105S are portions of the seal ring structure 100A and extend from a second region R2 of the substrate 101 in a <100> direction of the substrate 101.

As illustrated in FIG. 8, since the second active fins 105S extending in the <100> direction have a {100} crystal plane that is more advantageous for growth of an epitaxial (e.g., SiGe) layer than a {110} crystal plane of the first active fins 105, the second epitaxial pattern 130S may grow with a relatively large effective thickness in the second active fins 105S.

FIG. 10 is a graph illustrating an effective thickness of silicon germanium grown according to a crystal plane of silicon. Here, the effective thickness (th_{eff}) represents a volume of silicon germanium that grows per unit area of silicon. An effective thickness of SiGe (i.e., a first epitaxial pattern 130) grown from a first active fin 105 in a <110> direction has little to no change depending on a line width of the first active fin 105, whereas an effective thickness of SiGe (i.e., a second epitaxial pattern 130S) grown from a second active fin in a <100> direction has a generally larger effective thickness than that of the first epitaxial pattern 130, and in particular, the smaller the line width (w), the greater the effective thickness.

Accordingly, with an increase in scale-down of a semiconductor device 200, the second epitaxial pattern 130S may be grown with a relatively large effective thickness, that is, a large volume, in the second active fin 105S in the <100> direction.

Accordingly, when forming a source/drain, the second epitaxial pattern 130S having a relatively large effective thickness may be grown in the second active fin 105S of a sealing region R2, thus effectively consuming residual source gases concentrated on an edge region (especially edge region B1), and accordingly, the first epitaxial pattern 130 disposed in an edge region B1 may be prevented from being overgrown.

As described in FIG. 9A and FIG. 9B, the first epitaxial pattern 130 has a cross-section that is substantially pentagonal in a direction (e.g., the Y-direction), perpendicular to an extension direction (e.g., the X-direction) of the first active fin 105, and as illustrated in FIG. 8, the second epitaxial pattern 130S may have a substantially rectangular cross-section in a direction D2 or D1, perpendicular to an extending direction D1 or D2 of the second active fin 105S. As described above, the cross-section of the second epitaxial pattern 130S may have a shape different from that of the first epitaxial pattern 130. Furthermore, the cross-section of the second epitaxial pattern 130S may have a cross-sectional area greater than that of the first epitaxial pattern 130.

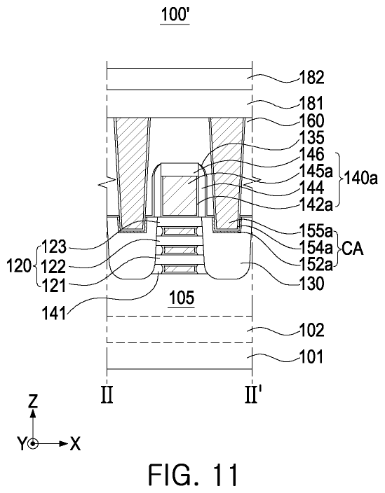

FIG. 11 illustrates another integrated circuit structure 100′ that may be adopted in a semiconductor device 200 according to an example embodiment of the present disclosure. A cross-section of FIG. 11 may be understood as a cross-section corresponding to FIG. 6.

Referring to FIG. 11, an integrated circuit structure 100′ according to an example embodiment of the present disclosure may further include a channel structure 120 including a plurality of channel layers 121, 122, and 123 vertically spaced apart from each other on a first active fins 105. The gate electrode 145a may be disposed between the active fins 105 and a channel structure 120 and between the plurality of channel layers 121, 122, and 123, and may be disposed above the channel structure 120. The integrated circuit structure 100′ according to an example embodiment of the present disclosure may include a Multi Bridge Channel FET (MBCFET™) by the channel structure 120, source/drain regions 130, and the gate structure 140a.

The gate structure 140a of the integrated circuit structure 100′ may further include internal spacers 141. The internal spacers 141 may be disposed in parallel with the gate electrode 145a between the channel structures 120. The internal spacers 141 may be disposed on both sides of the gate structure 140a in the X-direction on each lower surface of the first to third channel layers 121, 122, and 123. The internal spacers 141 may have external surfaces substantially coplanar with external surfaces of the first to third channel layers 121, 122, and 123. Under the third channel layer 123, the gate electrode 145a may be spaced apart from the source/drain regions 130 and electrically separated therefrom by the internal spacers 141. The internal spacers 141 may be formed of or include an oxide, a nitride, and an oxynitride, and specifically, may be formed of a low dielectric constant layer.

In an example embodiment of the present disclosure, the second active fin 105S disposed in the sealing region R2 may also be changed into a fin structure including first semiconductor patterns corresponding to a plurality of channel layers stacked on the second active fin 105S and second semiconductor patterns used as a sacrificial layer between the first semiconductor patterns. Even in this case, the fin structure including the second active fin 105S extends in a <100> crystal direction different from a direction of the first active fin 105.

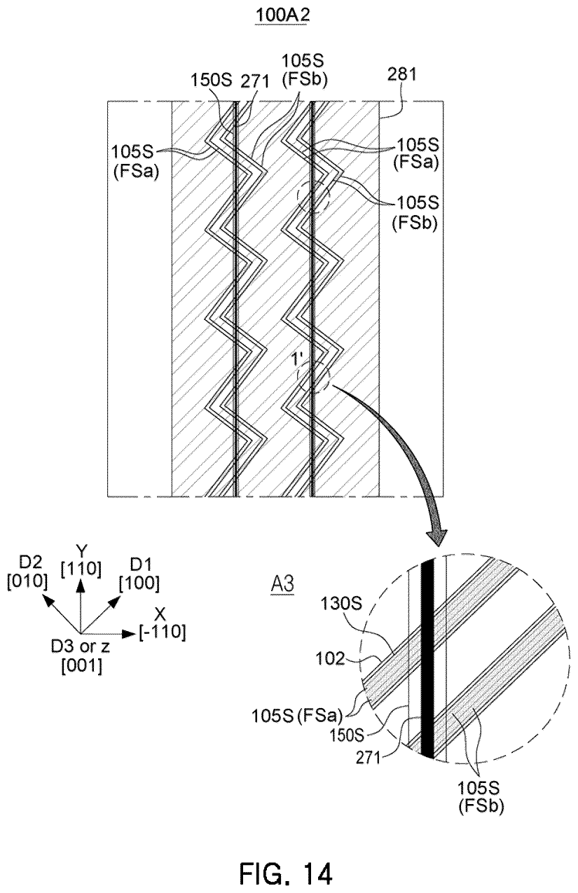

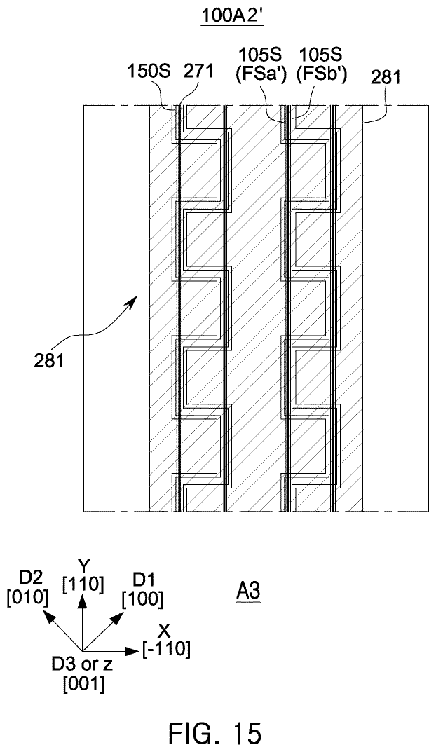

FIG. 12 is a schematic plan view illustrating a semiconductor device according to an example embodiment of the present disclosure, FIG. 13 is a partially enlarged view illustrating a corner region A2 of a first sealing region of a semiconductor device according to an example embodiment of the present disclosure, and FIG. 14 is a plan view illustrating a second partial region A3 of a semiconductor device according to an example embodiment of the present disclosure.

Referring to FIG. 12, a semiconductor device 200A according to an example embodiment of the present disclosure may be understood as being similar to the example embodiment illustrated in FIGS. 1 and 10, except that the semiconductor device 200A has a hexagonal device region R1 and first and second sealing regions R2 and R3, a partial region of a first seal ring structure 100A1 of the first sealing region R2 is changed, and the second sealing region R3 has a second seal ring structure 100A2.

Furthermore, the components of an example embodiment of the present disclosure may be understood by referring to the description of the components identical to or similar to those of the example embodiment illustrated in FIGS. 1 to 10, unless otherwise described.

In a substrate 101, a device region R1 in which an integrated circuit structure is formed may have a hexagonal shape. The integrated circuit structure may include the integrated circuit structure described in FIGS. 6 to 9. First active fins (e.g., first active fins 105) in the device region R1 of the integrated circuit structure may extend in a <110> direction (e.g., the X-direction).

In an example embodiment of the present disclosure, a sealing region may include a first sealing region R2 surrounding the device region R1 and a second sealing region R3 surrounding the first sealing region R2. The first seal ring structure 100A1 is disposed in the first sealing region R2, and the second seal ring structure 100A2 is disposed in the second sealing region R3.

The first seal ring structure 100A1 adopted in an example embodiment of the present disclosure includes side structures arranged along the four sides of the substrate 101, and corner structures arranged in a diagonal direction (D1 or D2) on each corner of the substrate 101. A partial region Al of the side structure may be understood as being the same as the enlarged views of partial region A of FIGS. 2 and 3. As described in FIGS. 2 and 3, the side structure adopted in an example embodiment of the present disclosure may have a pattern in which inclined rectangular phases are repeated, and may include first to third fin structures FS1, FS2, and FS3.

FIG. 13 is a partially enlarged view illustrating a corner region A2 of a first sealing region of a semiconductor device 200A according to an example embodiment of the present disclosure.

Referring to FIG. 13, a corner structure of a first seal ring structure 100A1 includes two pairs (four) of fin structures FS1′ and FS2′, each having two second active fins 105S. Each of the second active fins 105S may extend lengthwise in a diagonal direction, that is, in a <100> crystal direction, so as to connect adjacent side structures at a corner of the substrate 101.

The second active fins 105S constituting the corner structure illustrated in FIG. 13 are illustrated as extending lengthwise in a direction D2 (e.g., [010]), but second active fins 105S constituting the other corner structures may also extend lengthwise in a direction D1 (e.g., [100]).

Similarly to the previous example embodiment, a second epitaxial pattern 130S disposed on the second active fin 105S extending in the <100> direction of the substrate 101, and a second contact structure 150S connected to the second epitaxial pattern 130S may be further included on a sealing region R2 of the substrate 101. The second epitaxial pattern 130S may extend from an upper surface of the second active fin 105S in a <100> direction. In this manner, since the second epitaxial pattern 130S is formed over a sufficient area on the second active fin 105S, residual source gas concentrating on a device region R1 may be effectively consumed. In some example embodiments of the present disclosure, the second epitaxial pattern 130S may be formed substantially over an entire upper surface of the second active fins 105S. The second epitaxial pattern 130S has a substantially rectangular shape when viewed from a cross-section in the direction D1, perpendicular to an extension direction (e.g., D2) of a second active fin 105S (see FIGS. 4A to 4C). The second epitaxial pattern 130S may have an upper surface substantially parallel to the upper surface of the substrate 101.

In an example embodiment of the present disclosure, the second contact structure 150S may be connected to the second epitaxial pattern 130S by penetrating through an interlayer insulating layer 160 (see FIGS. 4A and 4C). Furthermore, a second contact structure 150S may cross the second active fin 105S, that is, a line pattern extending in a first direction (e.g., the X-direction) and/or the second direction (e.g., the Y-direction) to intersect a partial region of the second epitaxial pattern 130S (see an enlarged part of FIG. 13). Furthermore, a second metal via 271 may include a plurality of line-type metal vias extending along a plurality of second contact structures 150S in the second direction (e.g., the Y-direction), respectively. Furthermore, a second metal line 281 adopted in an example embodiment of the present disclosure extends in the second direction (e.g., the Y-direction) and may have a width extended in the first direction (e.g., the X-direction).

A semiconductor device 200A according to an example embodiment of the present disclosure may include a second seal ring structure 100A2 surrounding a first seal ring structure 100A1 in a second sealing region R3. The second seal ring structure 100A2 may serve to block moisture penetration and crack propagation together with the first seal ring structure 100A1 from the outside of the first seal ring structure 100A1.

As illustrated in FIG. 14, a second seal ring structure 100A2 includes two pairs of fin structures FSa and FSb having two second active fins 105S, respectively. Similarly to the first and second fin structures FS1 and FS2 of FIG. 2, each pair of fin structures FSa and FSb may have patterns comprised of fin components in different directions belonging to a <100> crystal direction, respectively. Specifically, each pair of fin structures FSa and FSb may have a zigzag pattern in which first fin components extending in the direction D1 (e.g., [100]) and second fin components extending in the direction D2 (e.g., [010]), perpendicular to the direction D1, are alternately arranged.

In a second seal ring structure 100A2, a second contact structure 150S may have the second active fin 105S, that is, a line pattern extending in the first direction (e.g., the X-direction) and/or the second direction (e.g., the Y-direction) to intersect a partial region of a second epitaxial pattern 130S, and a second metal via 271 may include a plurality of line-type metal vias respectively extending along a plurality of second contact structures 150S in the second direction (e.g., the Y-direction). Furthermore, a second metal line 281 may extend in the second direction (e.g., the Y-direction) and may have a width extending in the first direction (e.g., the X-direction).

Since the second seal ring structure 100A2 is not adjacent to an overgrowth region as compared to the first seal ring structure 100A1, it may have a <110> direction similarly to the first active fin of an integrated circuit region R1, not a <100> crystal direction. FIG. 15 is a plan view illustrating an arrangement of another second seal ring structures 100A2′ that may be adopted in a semiconductor device 200A according to an example embodiment of the present disclosure.

Referring to FIG. 15, a second seal ring structure 100A2′ includes two pairs of fin structures FSa and FSb, each having two second active fins 105S. Similarly to the first active fin, each pair of fin structures FSa′ and FSb′ may have patterns comprised of fin components in different directions belonging to a <110> crystal direction. Specifically, each pair of fin structures FSa′ and FSb′ may have an uneven pattern in which first fin components extending in an X-direction (e.g., [−110]) and second fin components extending in a Y-direction (e.g., [110]), perpendicular to the X-direction, are alternately arranged.

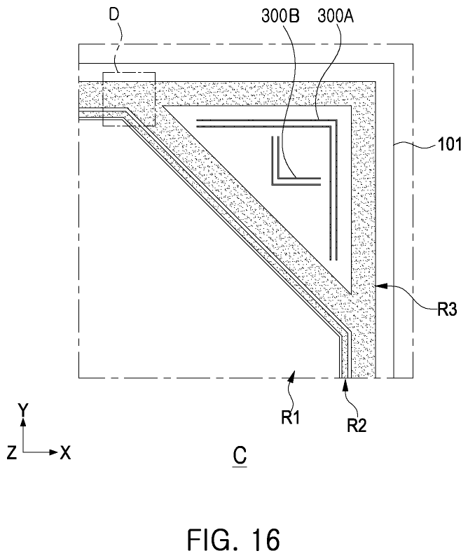

FIG. 16 is a partially enlarged view illustrating a corner region C of a semiconductor device of FIG. 11.

Referring to FIG. 16, corner regions of first and second sealing regions R2 and R3 of a semiconductor device 200A according to an example embodiment of the present disclosure are illustrated. In a corner of the first sealing region R2, as described above, a first seal ring structure 100A1 may include fin structures extending in a diagonal direction, and a second seal ring structure 100A2 may be arranged in a triangular shape in a corner of the second sealing region R3. First and second corner rings 300A and 300B may be further disposed in a triangular arrangement. The first and second corner rings 300A and 300B may be spaced apart from each other, and may have an uneven shape similarly to the pattern illustrated in FIG. 15. The first and second corner rings 300A and 300B may additionally reinforce a corner region in which moisture penetration or crack propagation is vulnerable during a dicing process of the semiconductor device 200A.

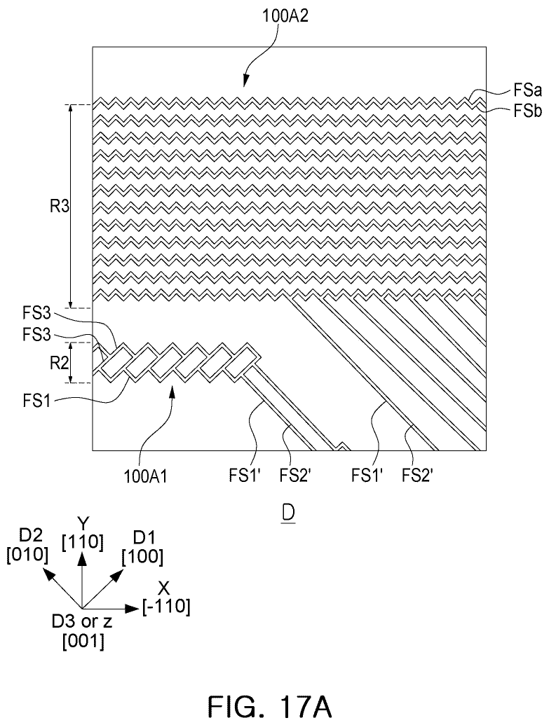

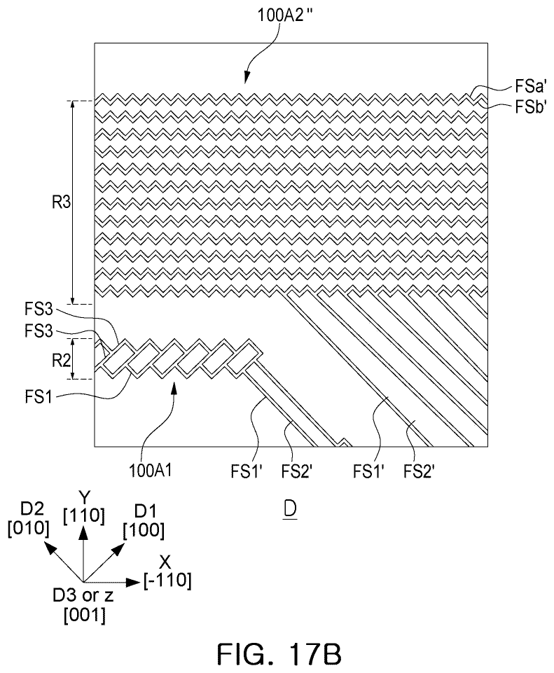

FIGS. 17A and 17B are plan views illustrating various examples of first and second sealing regions aligned in a partial region D of FIG. 16.

Referring to FIG. 17A, in a first sealing region R2, as described above, a first seal ring structure 100A1 includes fin structures FS1, FS2, and FS3 formed in a rectangular pattern inclined in the direction D1 (see FIGS. 2 and 3), and a corner portion of the first seal ring structure 100A1 has fin structures FS1′ and FS2′ extending in a diagonal direction, that is, in the direction D2.

In a second sealing region R3, a second sealing ring structure 100A2 includes a fin structure having a zigzag pattern in different directions of the <100> direction (see FIG. 14), and a corner portion of the second sealing ring structure 100A2 has fin structures FS1′ and FS2′ extending in the diagonal direction, that is, in the direction D2, similarly to the first seal ring structure 100A1.

Referring to FIG. 17B, a second seal ring structure 100A2″ may include a pair of fin structures FSa′ and FSb′ having a zigzag pattern in different directions of the <100> direction, and the pair of fin structures FSa′ and FSb′ may be symmetrically arranged based on a center line thereof. As described above, not only the first seal ring structure but also the second seal ring structure may be arranged in various patterns.

The seal ring structure adopted in the example embodiments of the present disclosure may be comprised of an active fin extending in the <100> direction of the substrate, different from an extension direction (<110> ) of the active fin of the integrated circuit structure. Since the active fin of the seal ring structure has a {100} crystal plane that is advantageous for epitaxial (e.g., SiGe) growth, the source gas remaining in an edge region of the substrate may be effectively consumed. Accordingly, a semiconductor device according to the example embodiment of the present disclosure may prevent defects due to overgrowth of the disadvantageous epitaxial layer generated in the edge of the device region.

The present disclosure is not limited to the above-described embodiments and the accompanying drawings. Therefore, those of ordinary skill in the art may make various replacements, modifications, or changes without departing from the scope of the present disclosure, and these replacements, modifications, or changes should be construed as being included in the scope of the present disclosure.

What is claimed is:

1. A semiconductor device comprising:
a substrate having a first region and a second region, the second region surrounding the first region;
an integrated circuit structure disposed on the first region of the substrate; and
a seal ring structure disposed on the second region of the substrate and surrounding the first region,
wherein the integrated circuit structure comprises:
a first active fin extending on the first region in a <110> crystal direction of the substrate, a gate structure intersecting the first active fin on the first region, a first epitaxial pattern disposed on one region of the first active fin on at least one side of the gate structure and provided to a source/drain region, and a first contact structure connected to the first epitaxial pattern, and wherein the seal ring structure comprises:
a second active fin extending on the second region in a <100> crystal direction of the substrate, a second epitaxial pattern disposed on the second active fin and including the same material as that of the first epitaxial pattern, and a second contact structure connected to the second epitaxial pattern.

2. The semiconductor device of claim 1, wherein the second epitaxial pattern has an effective thickness greater than an effective thickness of the first epitaxial pattern.

3. The semiconductor device of claim 1, wherein the first epitaxial pattern has a first cross-section in a direction perpendicular to an extension direction of the first active fin, the second epitaxial pattern has a second cross-section in a direction perpendicular to an extension direction of the second active fin, and the first cross-section has a shape different from that of the second cross-section.

4. The semiconductor device of claim 3, wherein the second cross-section has an area greater than that of the first cross-section.

5. The semiconductor device of claim 1, wherein the second epitaxial pattern extends on an upper surface of the second active fin in an extension direction of the second active fin.

6. The semiconductor device of claim 5, wherein the second contact structure extends in a direction intersecting the extension direction of the second active fin and is connected to one region of the second epitaxial pattern.

7. The semiconductor device of claim 5,
wherein the second contact structure includes a plurality of contact structures extending in a direction intersecting the extension direction of the second active fin, and
wherein each of the plurality of contact structures is connected to one region of the second epitaxial pattern.

8. The semiconductor device of claim 1, wherein the second active fin has a pattern in which first fin components extending in a first direction of the <100> crystal direction, and second fin components extending in a second direction perpendicular to the first direction of the <100> crystal direction, are connected to each other.

9. The semiconductor device of claim 8, wherein the second active fin has a zigzag pattern, in which the first and second fin components are alternately arranged.

10. The semiconductor device of claim 8, wherein the second active fin has a rectangular pattern including two first fin components and two second fin components.

11. The semiconductor device of claim 1,
wherein the integrated circuit structure further includes a first wiring structure having a first metal via connected to the first contact structure and a first metal line connected to the first metal via, and the seal ring structure further includes a second wiring structure having a second metal via connected to the second contact structure and a second metal line connected to the second metal via, and
wherein the second metal via is disposed on a level corresponding to the first metal via, and the second metal line is disposed on a level corresponding to the first metal line.

12. The semiconductor device of claim 11, wherein the second metal line has a width corresponding to a region in which the second active fin is arranged and a length that extends to surround the first region.

13. The semiconductor device of claim 1,
wherein the integrated circuit structure further includes a plurality of channel layers spaced apart from each other in a direction perpendicular to an upper surface of the substrate on the one region of the first active fin, and
wherein the gate structure includes a gate electrode intersecting the one region of the first active fin and surrounding the plurality of channel layers, and gate spacers disposed on both side surfaces of the gate electrode, respectively.

14. A semiconductor device comprising:
a substrate having a first region and a second region, the second region surrounding the first region;
a first active fin extending on the first region of the substrate in a <110> crystal direction;
a gate structure intersecting one region of the first active fin on the second region of the substrate;
a first epitaxial pattern disposed on the first active fin on both sides of the gate structure and provided to a source/drain region;
a second active fin extending on the second region in a <100> crystal direction of the substrate and surrounding the first region; and
a second epitaxial pattern disposed on the second active fin and including the same material as that of the source/drain region,
wherein the first epitaxial pattern has a first cross-section in direction perpendicular to an extension direction of the first active fin, the second epitaxial pattern has a second cross-section in a direction perpendicular to an extension direction of the second active fin, and the first cross-section has a shape different from that of the second cross-section and has an area greater than that of the second cross-section.

15. The semiconductor device of claim 14, wherein the first and second active fins include silicon (Si), and the first and second epitaxial patterns include silicon-germanium (SiGe).

16. The semiconductor device of claim 15, wherein the first cross-section of the first epitaxial pattern has a pentagonal shape, and the second epitaxial pattern has an upper surface in parallel with an upper surface of the substrate.

17. The semiconductor device of claim 14,
wherein the second active fin includes a plurality of fin components, and
each of the plurality of active fins has a pattern including first fin components extending in a first direction of the <100> crystal direction, and second fin components extending in a second direction perpendicular to the first direction of the <100> crystal direction.

18. The semiconductor device of claim 17,
wherein the plurality of active fins are divided into a plurality of fin structures including two or more adjacent active fins, and
wherein active fins of each of the plurality of active fins have the same pattern from a plan view.

19. The semiconductor device of claim 18, wherein active fins of at least one of the plurality of fin structures have a different pattern from active fins of other fin structures from a plan view.

20. A semiconductor device comprising:
a substrate having a device region and a sealing region surrounding the device region;
an integrated circuit structure disposed on the device region of the substrate;
a first seal ring structure disposed on an internal region of the sealing region of the substrate and surrounding the device region; and
a second seal ring structure disposed on an external region of the sealing region of the substrate and surrounding the first seal ring structure,
wherein the integrated circuit structure includes a first active fin extending on the device region in a <110> crystal direction of the substrate, a gate structure intersecting the first active fin on the device region of the substrate, a first epitaxial pattern disposed on one region of the first active fin on at least one side of the gate structure and provided to a source/drain region, and a first contact structure connected to the first epitaxial pattern,
wherein the first seal ring structure includes a second active fin extending on the internal region of the sealing region in a <100> crystal direction of the substrate, a second epitaxial pattern extending in an extending direction of the second active fin on the second active fin and including the same material as that of the first epitaxial pattern, and a second contact structure connected to one region of the second epitaxial pattern, and
wherein the second seal ring structure includes a third active fin extending on the external region of the sealing region in a <100> crystal direction or a <110> crystal direction of the substrate, and a third contact structure connected to the third active fin.
